(19) United States
(12) Patent Application Publication
(10) Pub. No.: US 2020/0020651 A1
(43) Pub. Date: Jan. 16, 2020

(54) RADIO-FREQUENCY MODULE

(71) Applicant: FUJITSU COMPONENT LIMITED, Tokyo (JP)

(72) Inventors: Shigemi Kurashima, Tokyo (JP); Mitsuki Kanda, Tokyo (JP); Takatoshi Yagisawa, Tokyo (JP)

(21) Appl. No.: 16/507,226

(22) Filed: Jul. 10, 2019

(30) Foreign Application Priority Data
Jul. 13, 2018 (JP) 2018-132863

(51) Int. Cl. H01L 23/60; H01L 23/66

(52) U.S. Cl. CPC H01L 23/60; H01L 23/66; H03H 7/06; H01L 2223/6616; H01L 2223/6627

(57) ABSTRACT

A radio-frequency module includes a semiconductor device, a first signal line configured to transmit an electrical signal to the semiconductor device, a ground electrode, and a first discharge unit situated between the first signal line and the ground electrode, wherein the first discharge unit includes a first projection formed on the ground electrode and a second projection formed on the first signal line, and the first projection and the second projection are situated opposite each other, with a predetermined distance therebetween, and wherein when an effective wavelength of the transmitted electrical signal is denoted as λg, and a length of the first projection is denoted as L, λg and L are related as:

0<(L/λg)≤0.1.

### BACKGROUND OF THE INVENTION

### 1. Field of the Invention

The disclosures herein relate to a radio-frequency module.

### 2. Description of the Related Art

High-speed interface for supercomputers and servers used to employ metallic wires and cables, but has recently been increasingly employing optical communications to achieve high-speed transmission and to increase transmission distance. Optical communications involve use of optical modules for connecting optical fibers and servers. Optical modules convert optical signals from optical fibers into electrical signals, and convert electrical signals from servers into optical signals.

Such optical modules use radio-frequency (RF) electrical signals, and are regarded as one type of radio-frequency module.

High voltage caused by static electricity applied to an optical module may damage the semiconductor device. In consideration of this, measures against ESD (electrostatic discharge) are usually taken. Anti-ESD measures with respect to an optical module are evaluated, through an HBM (human-body-model) based ESD test, for example, by checking whether specified criterion are satisfied.

Accordingly, there may be a need for an RF module which has satisfactory ESD resistance.

### RELATED-ART DOCUMENTS

### Patent Document

### [Patent Document 1] Japanese Patent Application Publication No. 2018-17861

[Patent Document 2] Japanese Patent Application Publication No. H11-26185

### [Patent Document 3] Japanese Patent Application Publication No. 2001-135897

[Patent Document 4] Japanese Utility Model Publication No. S53-135561

### [Patent Document 5] Japanese Patent Application Publication No. 2004-79529

### SUMMARY

According to an embodiment, a radio-frequency module includes a semiconductor device, a first signal line configured to transmit an electrical signal to the semiconductor device, a ground electrode, and a first discharge unit situated between the first signal line and the ground electrode, wherein the first discharge unit includes a first projection formed on the ground electrode and a second projection formed on the first signal line, and the first projection and the second projection are situated opposite each other, with a predetermined distance therebetween, and wherein when an effective wavelength of the transmitted electrical signal is denoted as λg, and a length of the first projection is denoted as L, λg and L are related as:

0<(L/λg)≤0.1.

According to at least one embodiment, a radio-frequency module has satisfactory ESD resistance.

### BRIEF DESCRIPTION OF THE DRAWINGS

FIG. 1 illustrates an RF module of a first embodiment;

FIG. 2 illustrates the HBM;

FIG. 3 illustrates a first discharge unit of the first embodiment;

FIG. 4 illustrates another first discharge unit;

FIG. 5 illustrates a simulation model;

FIG. 6 illustrates the simulation model;

FIG. 7 is a characteristic chart of transmission loss S21 obtained by a simulation;

FIG. 8 illustrates a simulation model;

FIG. 9 illustrates the simulation model;

FIG. 10 is a characteristic chart of transmission loss S21 obtained by a simulation;

FIG. 11 illustrates a simulation model;

FIG. 12 is a characteristic chart of transmission loss S21 obtained by a simulation;

FIG. 13 illustrates the correlation between L/λg and transmission loss S21;

FIG. 14 illustrates an RF module of the first embodiment;

FIG. 15 illustrates another RF module;

FIG. 16 illustrates a variation of a first discharge unit according to the first embodiment;

FIG. 17 illustrates another variation of a first discharge unit;

FIG. 18 illustrates yet another variation of a first discharge unit;

FIG. 19 illustrates an RF module of a second embodiment; and

FIG. 20 illustrates a variation of an RF module.

### DESCRIPTION OF EMBODIMENTS

Embodiments for implementing the invention will be described. The same members are referred to by the same numerals, and a description thereof will be omitted.

### First Embodiment

A radio-frequency (RF) module of a first embodiment will be described. In the present application, the term “radio-frequency” means frequencies higher than or equal to 1 GHz and lower than or equal to 100 GHz.

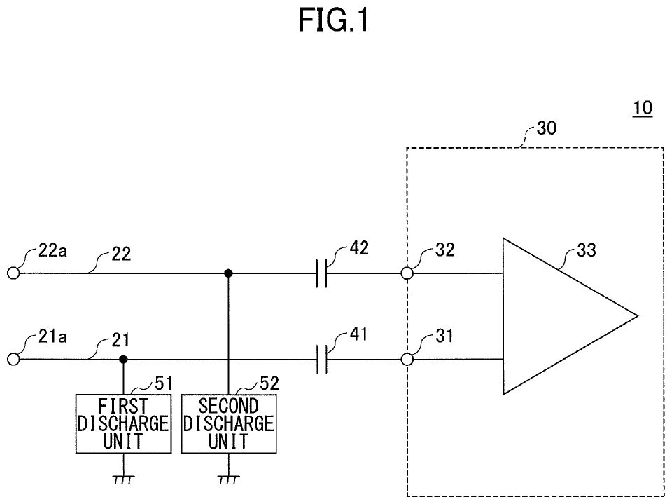

As illustrated in FIG. 1, an RF module 10 of the present embodiment includes a first line 21 and a second line 22 into which RF signals are input, a semiconductor device 30, a first capacitor 41 situated between the first line 21 and a terminal 31 of the semiconductor device 30, a second capacitor 42 situated between the second line 22 and a terminal 32 of the semiconductor device 30, a first discharge unit 51 situated between the first line 21 and the ground potential, and a second discharge unit 52 situated between the second line 22 and the ground potential.

The RF signal input into an input terminal 21a is supplied to the terminal 31 through the first line 21 and the first capacitor 41. Similarly, the RF signal input into an input terminal 22a is supplied to the terminal 32 through the second line 22 and the second capacitor 42. An integrated circuit (IC) 33 is provided in the semiconductor device 30. The RF signals input into the terminal 31 and the terminal 32 are supplied to the IC 33 for signal processing.

The first capacitor 41 removes the DC component, and AC components are input into the terminal 31. The second capacitor 42 removes the DC component, and AC components are input into the terminal 32.

When part of a human body carrying accumulated static electricity comes in contact with the first line 21 or the second line 22, the first line 21 or the second line 22 exhibits a sudden voltage rise, which may reach and damage the IC 33. The DC component of static electricity is not input into the IC 33 because the DC component is removed by the first capacitor 41 and the second capacitor 42. However, the AC components pass through the first capacitor 41 and the second capacitor 42 to reach the IC 33.

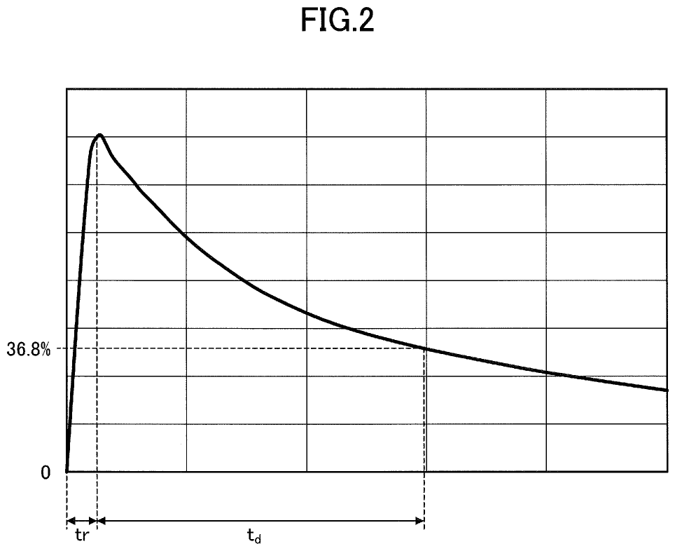

Standard No. 22-A114C.01 is adopted by JEDEC (Joint Electron Device Engineering Council) as the HBM ESD standard. The HBM ESD test requires sufficient tolerance even when a waveform as illustrated in FIG. 2 with a peak of 1000 V, a rise time tr of 2 to 10 ns, and an attenuation time td of 130 to 170 ns, for example, is applied.

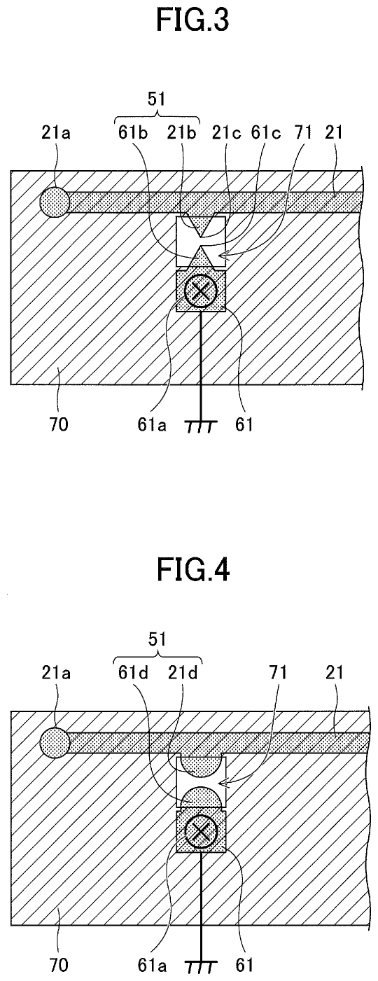

As illustrated in FIG. 3, the first discharge unit 51 includes a projection 21b formed on the first line 21 and a projection 61b formed on a ground electrode 61. A tip 21c of the projection 21b and a tip 61c of the projection 61b are situated opposite each other. The shapes of the projection 21b and the projection 61b are symmetrical with each other.

In the present embodiment, the tip 21c and the tip 61c are pointed to minimize the capacitance between the first line 21 and the ground electrode 61. The first discharge unit 51 is arranged such as to be exposed in an opening 71 of a resist 70. The ground electrode 61 is coupled to the back face of a substrate through a via 61a. The second discharge unit 52 has the same configuration as the first discharge unit 51. The first line 21 and the second line 22 are microstrip lines.

Alternatively, as illustrated in FIG. 4, the first discharge unit 51 may be implemented as a semicircular projection 21d and a semicircular projection 61d, such that the projection 21d and the projection 61d are situated opposite each other. The second discharge unit 52 has the same configuration as the first discharge unit 51.

In the following, the results of simulation performed with respect to the RF module according to the present embodiment will be described. When an RF signal is input into the signal line of the RF module 10, the RF signal may be reflected at the projection 21b, resulting in an increase in transmission loss in some cases.

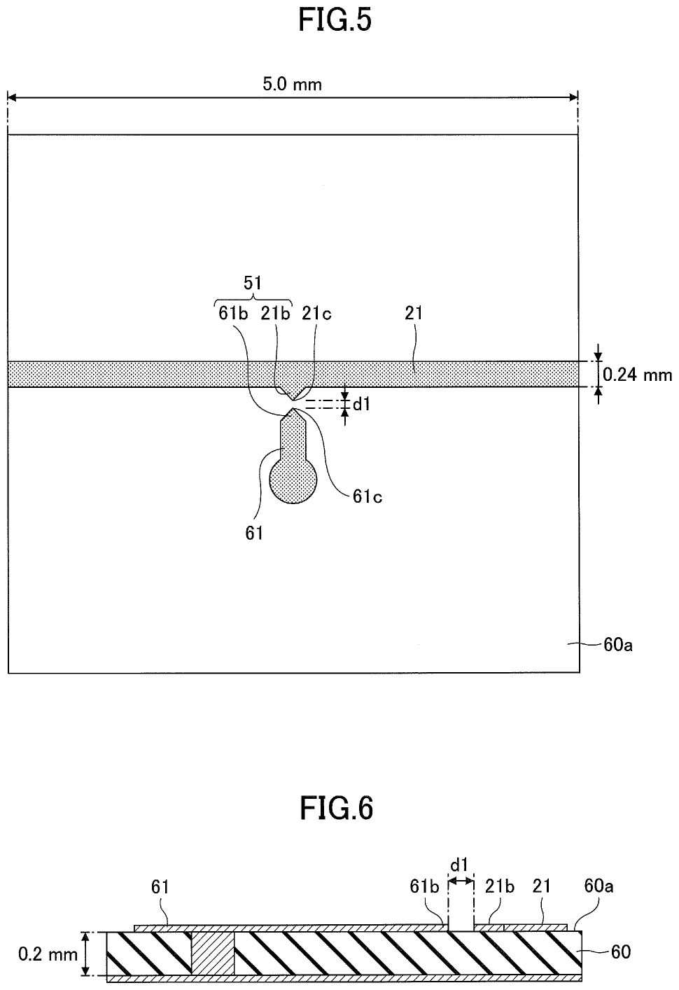

A simulation performed using the model illustrated in FIG. 5 and FIG. 6 with respect to the first discharge unit 51 of FIG. 3 will be described. In this model, the first line 21 and the ground electrode 61 were formed on a surface 60a of an insulating substrate 60 that is 0.2 mm in thickness. The first line 21 and the ground electrode 61 were made of a metallic material such as copper having a thickness of 0.01 mm. The length of the first line 21 is 5.0 mm with the width thereof being 0.24 mm. The projection 21b extended 0.1 mm laterally from the side edge of the first line 21. The projection 61b also had a pointed shape similar to the projection 21b. The distance d1 between the tip 21c and the tip 61c is set to 0.1 mm to correspond to 1000 V.

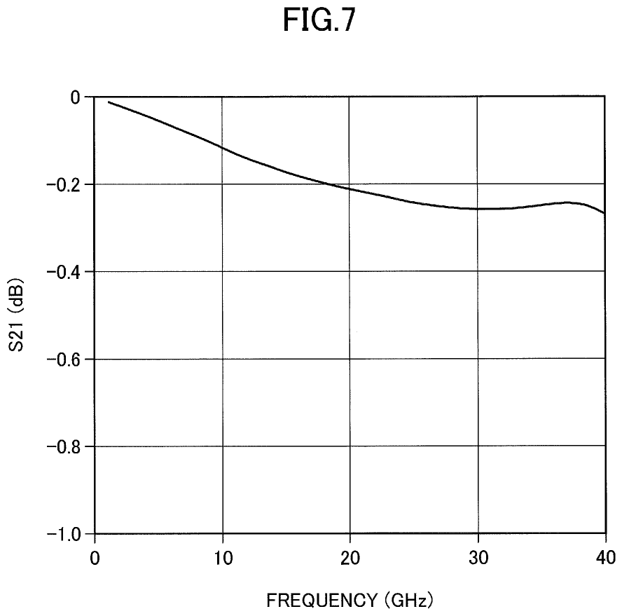

FIG. 7 illustrates a transmission loss S21, obtained by the simulation, of the signal output from the right end of the first line 21 in response to a signal input into the left end. As illustrated in FIG. 7, the transmission loss S21 was such that S21>−0.3 dB in a frequency range of 0 to 40 GHz. The transmission loss S21 is preferably less than 0.5 dB, and is also preferably less than 0.3 dB. In the model illustrated in FIG. 5 and FIG. 6, the transmission loss S21 was relatively small, and was within a viable range.

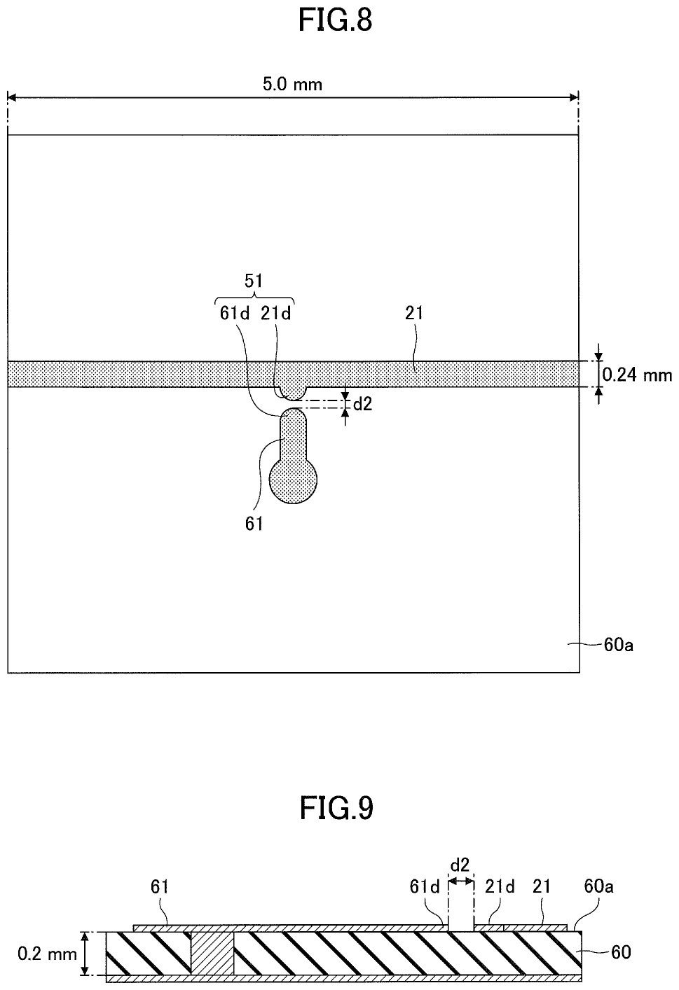

A simulation performed using the model illustrated in FIG. 8 and FIG. 9 with respect to the first discharge unit 51 of FIG. 4 will be described. In this model also, the first line 21 and the ground electrode 61 are formed on the surface 60a that is 0.2 mm in thickness. The first line 21 and the ground electrode 61 have a thickness of 0.01 mm. The length of the first line 21 is 5.0 mm, with the width thereof being 0.24 mm. The projection 21d having a radius of 0.1 mm, extended 0.1 mm from the first line 21. The projection 61d has the same or similar shape as the projection 21d. The distance d2 between the projection 21d and the projection 61d is set to 0.1 mm.

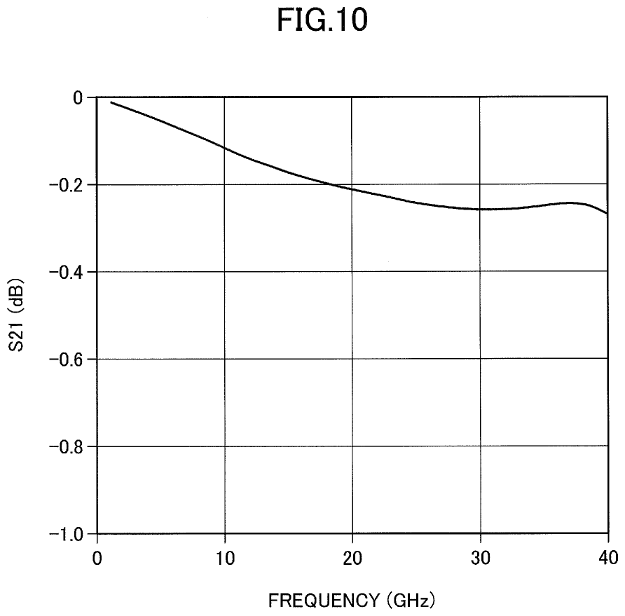

FIG. 10 illustrates a transmission loss S21, obtained by the simulation, of the signal output from the right end of the first line 21 of FIG. 8 in response to a signal input into the left end. The transmission loss S21 was such that S21>−0.3 dB in a frequency range of 0 to 40 GHz. Namely, the transmission loss was within a viable range.

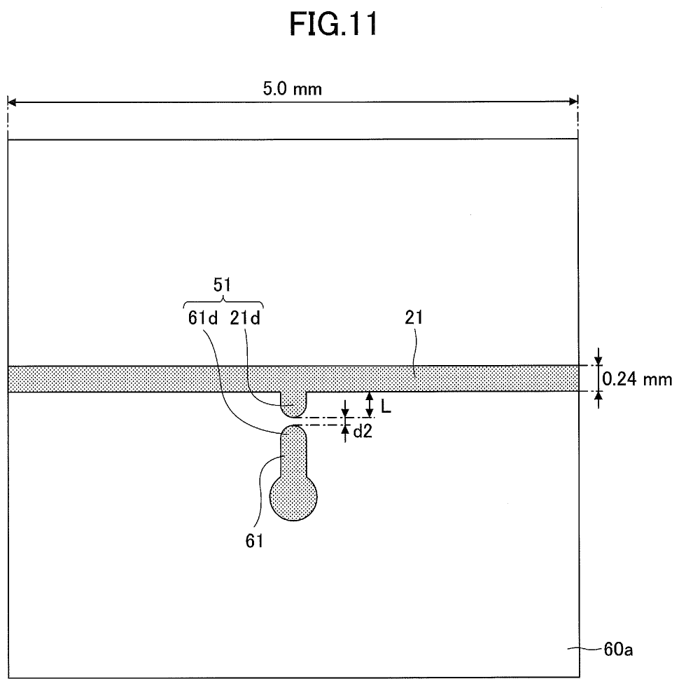

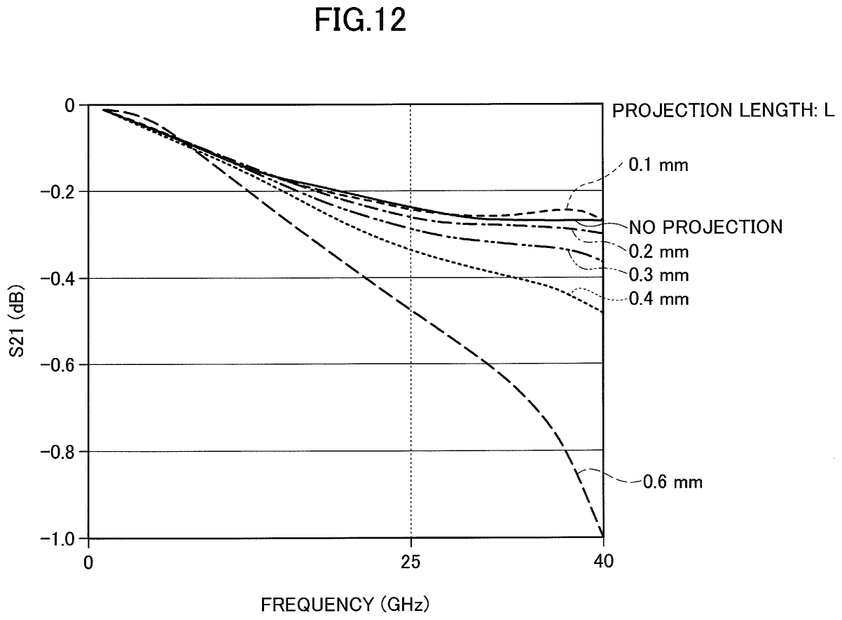

FIG. 12 illustrates the results of simulation when a length L of the projection 21d is changed as illustrated in FIG. 11 from the model of FIGS. 8 and 9. FIG. 12 also illustrates the results of a simulation with respect to an example in which no projection 21d is provided for comparison purposes.

In the absence of the projection 21d in the first discharge unit 51, the transmission loss S21 was −0.24 dB at a frequency of 25 GHz and −0.27 dB at a frequency of 40 GHz. When the length L of the projection 21d being 0.1 mm, S21 was −0.24 dB at 25 GHz and −0.27 dB at 40 GHz, similarly to the case of FIG. 10. When the length L being 0.2 mm, S21 was −0.26 dB at 25 GHz and −0.29 dB at 40 GHz. When the length L being 0.3 mm, S21 was −0.29 dB at 25 GHz and −0.36 dB at 40 GHz. When the length L being 0.4 mm, S21 was −0.34 dB at 25 GHz and −0.48 dB at 40 GHz. When the length L being 0.6 mm, S21 was −0.48 dB at 25 GHz and −1.0 dB at 40 GHz.

At a frequency of 25 GHz, the length of the projection 21d is preferably less than or equal to 0.6 mm, which provides the transmission loss S21 less than −0.5 dB, and is more preferably less than or equal to than 0.3 mm, which provides the transmission loss S21 less than −0.3 dB. At a frequency of 40 GHz, the length of the projection 21d is preferably less than or equal to 0.4 mm, which provides the transmission loss S21 less than −0.5 dB, and is more preferably less than or equal to than 0.2 mm, which provides the transmission loss S21 less than −0.3 dB.

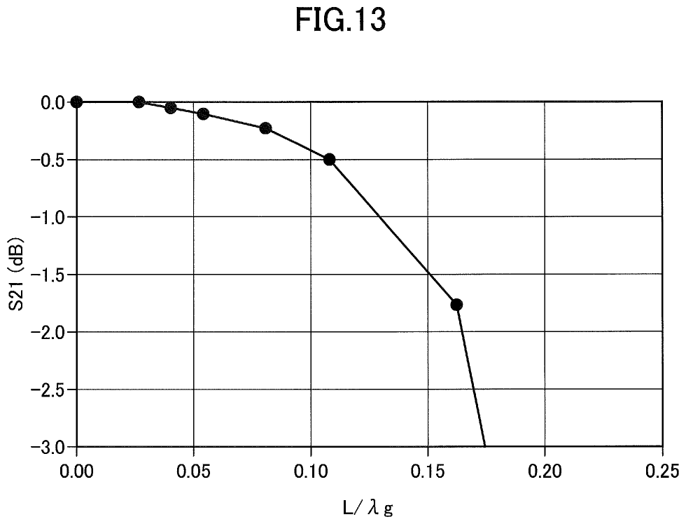

FIG. 13 illustrates the relationship between the transmission loss S21 and a projection length normalized by an effective wavelength λg (L/λg). FIG. 13 indicates that S21>−0.5 dB is achieved by 0<L/λg≤0.1, and S21>−0.3 dB is achieved by 0<L/λg≤0.08. An effective relative permittivity εreff of the structure illustrated in FIG. 11 is taken to be 2.63. Based on this eεreff, λg at 25 GHz is derived to be 7.4 mm. When the maximum frequency of an RF signal used in the RF module is 2.5 GHz, L (=λg/10) is 0.74 mm in the case of L/λg being 0.1, and L is 0.59 mm in the case of L/λg being 0.08.

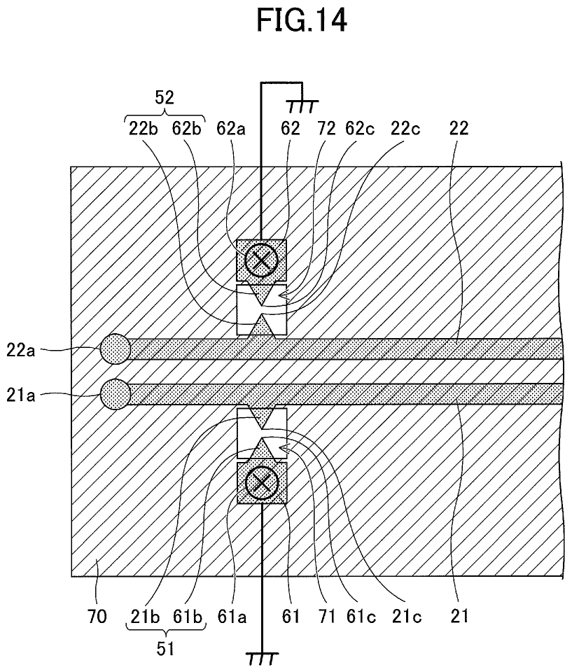

The structure illustrated in FIG. 14 may alternatively be used in the present embodiment. In FIG. 14, the ground electrode 61 is disposed on the lower side of the drawing relative to the first line 21, with the projection 21b and the projection 61b situated opposite each other. A ground electrode 62 is disposed on the upper side of the drawing relative to the second line 22, with a projection 22b and a projection 62b situated opposite each other. The second discharge unit 52 is arranged such as to be exposed in an opening 72 of the resist 70. The ground electrode 62 is coupled to the back face of the substrate through a via 62a. The distance between a tip 22c of the projection 22b and a tip 62c of the projection 62b is equal to the distance between the tip 21c and the tip 61c.

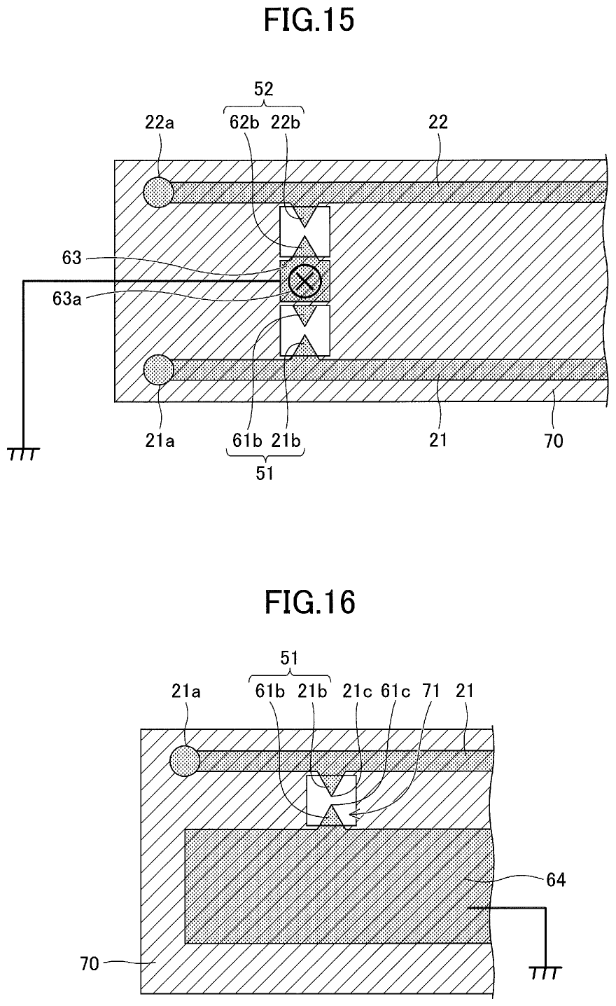

As illustrated in FIG. 15, a ground electrode 63 may be disposed between the first line 21 and the second line 22, with a projection 61b toward the first line 21 and a projection 62b toward the second line 22. The ground electrode 63 is coupled to the back face of the substrate through a via 63a. The structure illustrated in FIG. 15 allows the number of ground electrodes to be one, thereby reducing the size of an RF module.

### Variation

The RF module may be a coplanar line as illustrated in FIG. 16. In FIG. 16, a ground electrode 64 is disposed on the same surface of the substrate as the first line 21 in the absence of a via, and the ground electrode 64 has a projection 61b situated opposite the projection 21b. The same applies to the second line 22.

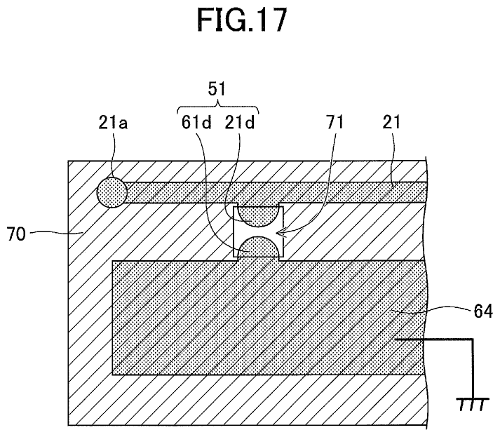

As illustrated in FIG. 17, the ground electrode 64 may be disposed on the same surface of the substrate as the first line 21 in the absence of a via, and a semicircular projection 61d is situated opposite the projection 21d. The same applies to the second line 22.

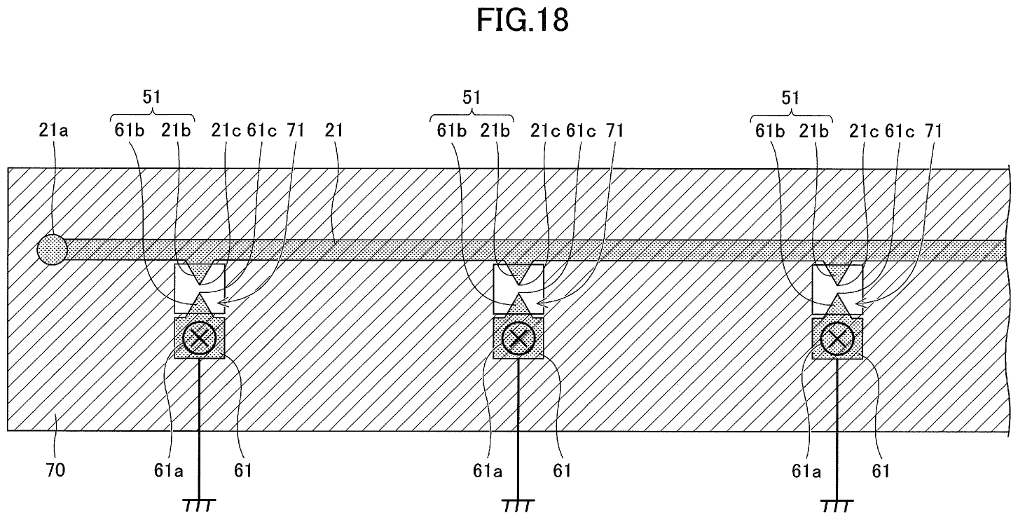

Alternatively, a plurality of first discharge units 51 may be provided on the first line 21 as illustrated in FIG. 18. In this case, ground electrodes 61 having projections 61b situated opposite the respective projections 21b are provided.

### Second Embodiment

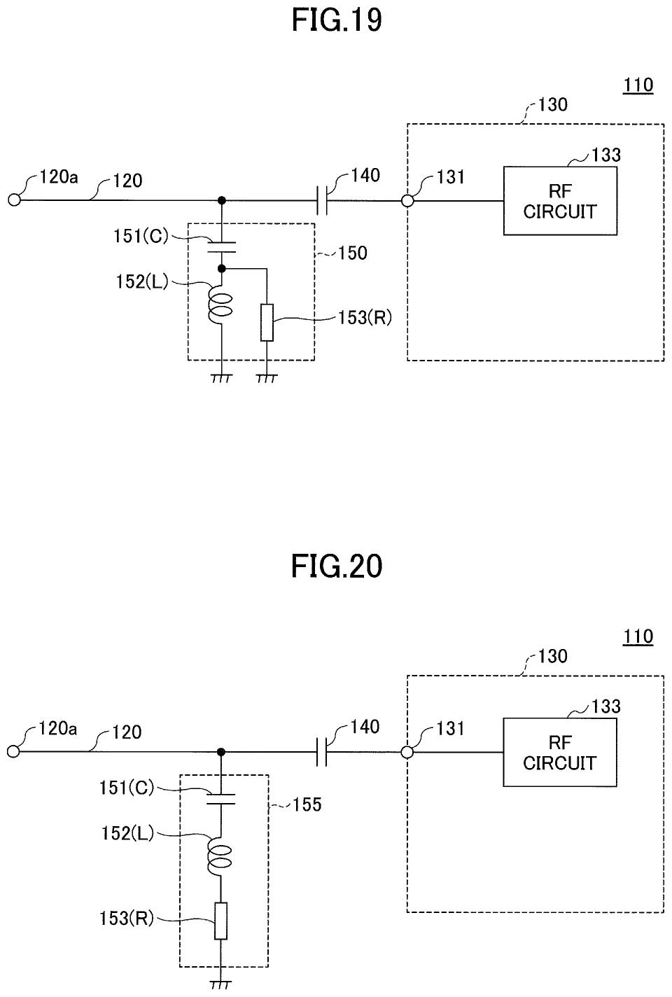

In the following, a second embodiment will be described. An RF module 110 of the present embodiment illustrated in FIG. 19 includes a signal line 120 into which an RF signal is input, a semiconductor device 130, a capacitor 140 situated between the signal line 120 and the semiconductor device 130, and a band-elimination filter 150 situated between the signal line 120 and the ground potential. An RF circuit 133 is disposed inside the semiconductor device 130.

An RF signal input into an input terminal 120a is supplied to a terminal 131 through the signal line 120 and the capacitor 140. The capacitor 140 removes the DC component, and the AC components are input into the terminal 131.

The filter 150 is connected to the signal line 120. The filter 150 is configured such that a capacitor 151 is connected in series to both a grounded coil 152 and a grounded resistor 153 connected in parallel.

When a cycle τ in the equivalent circuit of an HBM is set to 150 ns, the frequency corresponding to this period is 6.7 MHz. Accordingly, allowing signals having a frequency of 6.7 MHz to flow from the filter 150 to the ground terminal prevents the 6.7-MHz signals from entering the terminal 131, which can serve as a measure against ESD under the HBM. It may be noted that 6.7 MHz is outside the frequency band of RF signals used in the RF module, and is a sufficiently low frequency compared to RF signals. Therefore, the filter 150 thus does not affect RF signals transmitted on the signal line 120. In order to set a frequency transmitted through the filter 150 to 6.7 MHz, the capacitor 151 may be set to 100 pF, the coil 152 to 5.6 μH, and the resistor 153 to 2 kΩ. In the present embodiment, a signal having a certain frequency is transmitted through the filter 150 to the ground potential, and is thus prevented from entering the semiconductor device 130.

When a cycle τ in the HBM is set to 132 to 180 ns, the band-elimination filter may be configured such that the frequency transmitted through the filter 150 is greater than or equal to 5.5 MHz and less than or equal to 7.5 MHz.

A rise time tr and an attenuation time td in the HBM may be each considered to constitute a half of cycle τ. A rise time tr of 2 ns corresponds to a frequency of 250 MHz, and a rise time tr of 10 ns corresponds to a frequency of 50 MHz. An attenuation time td of 130 ns corresponds to a frequency of 3.8 MHz, and an attenuation time td of 170 ns corresponds to a frequency of 2.9 MHz. Accordingly, in order to provide protection for the frequency range noted above, the filter 150 is configured such that the frequencies transmitted through the filter 150 is greater than or equal to 2.9 MHz and less than or equal to 250 MHz.

The RF module may alternatively be configured such that a band-elimination filter 155 as illustrated in FIG. 20 is situated between the signal line 120 and the ground potential. The filter 155 is constituted by the capacitor 151, the coil 152, and the grounded resistor 153 connected in series. Similarly to the filter 150, the filter 155 is able to transmit only the frequency components corresponding to the HBM, thereby providing an effective anti-ESD measure for the RF module.

As was described heretofore, a filter allowing the passage or blockage of particular frequencies based on the equivalent circuit of the HBM prevents signals having particular frequencies from entering a semiconductor device, thereby reducing the effect of static electricity on the semiconductor device when a human body comes in contact with the RF module.

Other aspects than those described above are the same as or similar to those of the first embodiment.

Further, although a description has been given with respect to one or more embodiments of the present invention, the contents of such a description do not limit the scope of the invention.

The present application is based on and claims priority to Japanese patent application No. 2018-132863 filed on Jul. 13, 2018, with the Japanese Patent Office, the entire contents of which are hereby incorporated by reference.

What is claimed is:

1. A radio-frequency module, comprising:
a semiconductor device;
a first line configured to transmit an electrical signal to the semiconductor device;
a ground electrode; and
a first discharge unit situated between the first line and the ground electrode,
wherein the first discharge unit includes a first projection formed on the ground electrode and a second projection formed on the first line, and the first projection and the second projection are situated opposite each other, with a predetermined distance therebetween, and
wherein when an effective wavelength of the transmitted electrical signal is denoted as λg, and a length of the first projection is denoted as L, λg and L are related as:
0<(L/λg)≤0.1.

2. A radio-frequency module, comprising:
a semiconductor device;
a first line configured to transmit an electrical signal to the semiconductor device;
a ground electrode; and
a first discharge unit situated between the first line and the ground electrode,
wherein the first discharge unit includes a first projection formed on the ground electrode and a second projection formed on the first line, and the first projection and the second projection are situated opposite each other, with a predetermined distance therebetween, and
wherein a length of the first projection is less than or equal to 0.6 mm.

3. The radio-frequency module as claimed in claim 1, further comprising:
a second line configured to transmit an electrical signal to the semiconductor device; and
a second discharge unit,
wherein the ground electrode is situated between the first line and the second line, and
wherein the first discharge unit and the second discharge unit are situated between the ground electrode and the first line and between the ground electrode and the second line, respectively.

4. The radio-frequency module as claimed in claim 2, further comprising:
a second line configured to transmit an electrical signal to the semiconductor device; and
a second discharge unit,
wherein the ground electrode is situated between the first line and the second line, and
wherein the first discharge unit and the second discharge unit are situated between the ground electrode and the first line and between the ground electrode and the second line, respectively.

5. A radio-frequency module, comprising:
a semiconductor device;
a signal line configured to transmit an electrical signal to the semiconductor device; and
a band-elimination filter situated between the signal line and a ground potential,
wherein frequencies transmitted through the band-elimination filter are greater than or equal to 2.9 MHz and less than or equal to 250 MHz.
